(19) United States
(12) Patent Application Publication
(10) Pub. No.: US 2006/0202224 A1
(43) Pub. Date: Sep. 14, 2006

(54) Substrate structure for light-emitting diode module

(76) Inventor: Julian Lee, Taipei Hsien (TW)

Correspondence Address: PRO-TECTOR INTERNATIONAL SERVICES, 20775 NORADA CT., SARATOGA, CA, 95070, US

(21) Appl. No.: 11/076,242

(22) Filed: Mar. 8, 2005

(51) Int. Cl. H01L 33/00

(52) U.S. Cl. 257/99

(57) ABSTRACT

A substrate structure for light-emitting diode module includes a highly heat-radiating metal substrate, a plurality of isolating islands formed on a top surface of the metal substrate only at positions and/or paths for forming required conducting circuits, and a plurality of conduction islands separately formed on the isolating islands to constitute the required circuits on the metal substrate. At least one light emitting diode is mounted on the metal substrate with a heat radiating and conducting package section at a bottom thereof directly attaching to the top surface of the metal substrate, and two external electrode leads at an outer side of the package section electrically connected to corresponding conducting islands, so as to form a light-emitting diode module on the metal substrate.

### FIELD OF THE INVENTION

The present invention relates to a substrate structure, and more particularly to a substrate structure for light-emitting diode module.

### BACKGROUND OF THE INVENTION

A light emitting diode is a light-emitting element formed by using semiconducting materials of III-V group or II-IV group compounds and structural changes in different semiconductor elements. The light emitting diode is different from a conventional tungsten lamp in terms of the principle and structure for emitting light. Unlike the tungsten lamp that consumes high power, produces large quantity of heat, and has low impact resistance and short usable life, the light emitting diode has the advantages of small volume, prolonged usable life, low driving voltage, high response rate, high vibration resistance, etc., and is therefore widely employed in different electronic products, such as mobile communication devices, traffic signals, outdoor signboards, light sources for cars, etc.

The light emitting diode is constantly improved through continuous researches and developments to provide enhanced light efficiency and upgraded brightness, and is now more widely applied to various kinds of products to meet consumers' different demands. To increase the brightness of the light emitting diode, it is not only necessary to overcome the problem with the packaging of the light emitting diode, but also provide higher electrical power and further intensified working current to the light emitting diode. However, light emitting diode with higher electrical power and further intensified working current would produce increased heat and become overheated to adversely affect its performance or even result in burnout thereof.

FIG. 1 is a sectional view of a conventional substrate structure for light-emitting diode module, and FIG. 2 is a sectional view of a conventional light-emitting diode module 1′ formed on the substrate structure of FIG. 1. To solve the problem of heat produced by the light emitting diode during operation thereof, the conventional light-emitting diode module 1′ is typically formed on a metal substrate 10′ made of a metal material with relatively good heat conductivity, so that heat produced by a light emitting diode 20′ thereof is radiated via the metal substrate 10′. A surface of the metal substrate 10′ is polarized before an insulating layer 12′ and a conducting layer 14′ are sequentially superposed thereon by way of lamination. Thereafter, any non-useful portions of the conducting layer 14′ are removed from the top of the insulating layer 12′ using an etching process to expose the insulating layer 12′ therebelow, and other portions of the conducting layer 14′ are left to serve as conducting circuits. To mount the light emitting diode 20′ on the metal substrate 10′, a predetermined part of the exposed insulating layer 12′ is removed to expose the surface of the metal substrate 10′ therebelow for a package section 22′ at a bottom of the light emitting diode 20′ to attach thereto. Finally, external electrode leads 24′ of the light emitting diode 20′ are fixedly connected to the conducting layer 14′ by way of soldering. As can be seen from FIG. 2, the heat produced by the light emitting diode 20′ is partly dissipated into air via the external electrode leads 24′ and partly radiated into air via the metal substrate 10′, so that the light emitting diode 20′ is protected against an overly high working temperature.

More specifically, in the conventional substrate structure for light-emitting diode module as shown in FIG. 1, a considerably high amount of power is consumed to polarize the surface of the metal substrate 10′ and sequentially laminate complete sheets of insulating layer 12′ and conducting layer 14′ on the polarized surface of the metal substrate 10′. Moreover, it is found from the actual production of the conventional substrate structure for light-emitting diode module that the left portions of the etched conducting layer 14′ and the etched insulating layer 12′ for serving as conducting circuits and insulator, respectively, only occupy about 30% of the whole area of the metal substrate 10′. That is, the other 70% of the conducting and the insulating layer 14′ and 12′ are removed by way of etching process or other destructive manners. Therefore, the conventional substrate structure for light-emitting diode module requires a considerably high manufacturing cost due to the high power consumption in the manufacturing process thereof and the unnecessary waste of large quantity of the conducting and insulating materials thereof. Moreover, the etching process used to remove non-useful portions of the conducting and the insulating layer requires strong-acidity and strong-basicity chemical solvents, which tend to generate toxic gases and waste liquid containing strong acids and/or bases to result in environmental pollution.

### SUMMARY OF THE INVENTION

A primary object of the present invention is to provide a substrate structure for light-emitting diode module that could be produced with simplified process to largely reduce the energy consumption thereof and avoid undesirable environmental pollution.

Another object of the present invention is to provide a substrate structure for light-emitting diode module that has conducting circuits formed thereon in a simplified way to reduce unnecessary waste of material and thereby decrease the manufacturing cost thereof.

A further object of the present invention is to provide a substrate structure for light-emitting diode module on which multiple layers of conducting circuits can be formed to widen the application of the substrate structure to more different products.

To achieve the above and other objects, the substrate structure for light-emitting diode module according to the present invention mainly includes a highly heat-radiating metal substrate, a plurality of isolating islands formed on a top surface of the metal substrate only at positions and/or paths for forming required conducting circuits, and a plurality of conducting islands separately formed on the isolating islands to constitute the required circuits on the metal substrate. At least one light emitting diode is mounted on the metal substrate with a heat radiating and conducting package section at a bottom thereof directly attaching to the top surface of the metal substrate, and two external electrode leads at an outer side of the package section electrically connected to corresponding conducting islands, so as to form a light-emitting diode module on the metal substrate.

Since the isolating islands are formed by directly applying a heat-resisting resin material on the metal substrate only at predetermined positions and/or along predetermined paths for forming required conducting circuits and have shapes and areas determined in accordance with the required conducting circuits, and the conducting islands are formed by screen printing or applying a conducting material only on the top of the isolating islands, the conventional etching process for removing unnecessary portions of the isolating and conducting materials from the top of the metal substrate is omitted to largely simplify the whole manufacturing process for forming a light-emitting diode module on the metal substrate and save a large amount of electrical energy, insulating material, and conducting material. Moreover, the problem of environmental pollution caused by strong acids and bases used in the etching process could be avoided.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a sectional view of a conventional substrate structure for light-emitting diode module;

FIG. 2 is a sectional view of a conventional light-emitting diode module formed on the substrate structure of FIG. 1;

FIG. 3 is a sectional view of a substrate structure for light-emitting diode module according to a first embodiment of the present invention;

FIG. 4 is a sectional view of a light-emitting diode module formed on the substrate structure according to the first embodiment of the present invention; and

FIG. 5 is a sectional view of a substrate structure for light-emitting diode module according to a second embodiment of the present invention.

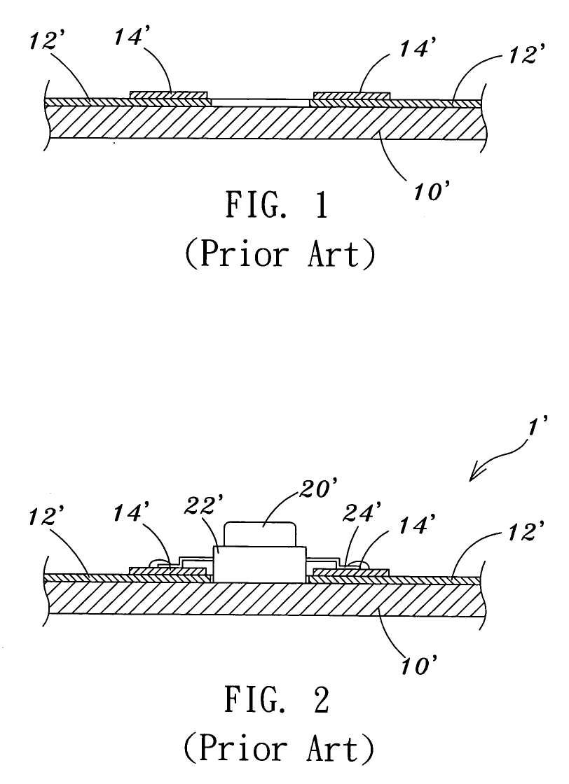

### DETAILED DESCRIPTION OF THE PREFERRED EMBODIMENTS

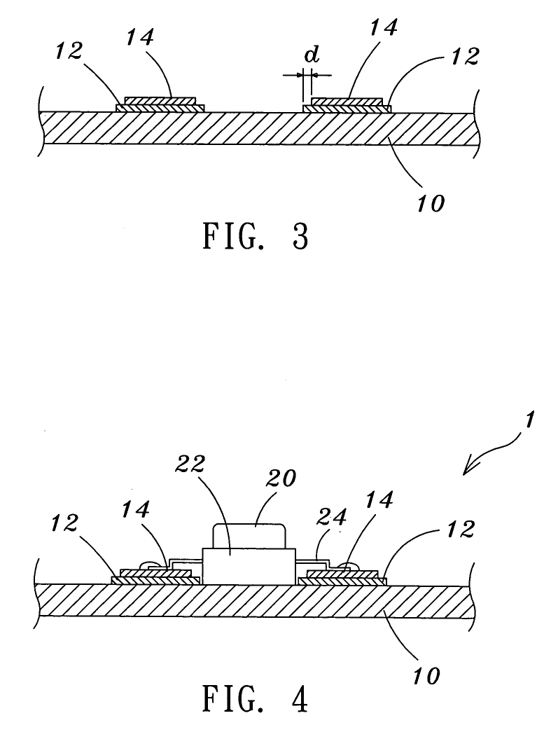

Please refer to FIG. 3 that shows a substrate structure for light-emitting diode module according to a first embodiment of the present invention. As shown, the substrate structure includes a highly heat-radiating metal substrate 10, on a top surface of which a plurality of isolating islands 12 are directly formed at positions and/or along paths at where required conducting circuits are to be provided. And, a conducting island 14 is provided on a top of each of the isolating islands 12 to provide a conducting circuit on the surface of the metal substrate 10.

Please refer to FIG. 4 that shows a light-emitting diode module 1 formed on the substrate structure of FIG. 3. As shown, the light-emitting diode module 1 includes more than one light emitting diode 20, which is attached to an exposed surface of the metal substrate 10 by way of surface mount technology (SMT). The light emitting diode 20 includes a package section 22, which is made of a heat conducting and radiating material and located at a bottom of the light emitting diode 20 to directly contact with the exposed surface of the metal substrate 10. Two external electrode leads 24 are provided at an outer side of the package section 22 and separately electrically connected to two corresponding conducting islands 14.

The metal substrate 10 is made of a metal sheet with good heat conductivity, such as copper or aluminum alloy sheet. The isolating island 12 is formed by directly applying a heat-resisting resin material over a predetermined position on the surface of the metal substrate 10. The heat-resisting resin material is preferably selected from the group consisting of polyimide, composite of BT resin (a polymer of Bismaleimidem and Triagzine Resin monomer) and epoxy resin, and other functionally equivalent heat conducting resins. Alternatively, the isolating island 12 may be formed from a material containing 50%˜90% of resin and 50%˜10% of graphite, or a material containing 50%˜90% of resin and 50%˜10% of boron nitride, so as to provide an insulating effect between the conducting island 14 and the metal substrate 10.

The conducting island 14 is formed by screen printing or directly applying a composite of different types of metal powder or conducting carbon fibers on the top surface of the isolating island 12. The metal powder contained in the composite for forming the conducting island 14 include particles of gold, silver, copper, iron, tin, magnesium, and aluminum, and/or the oxides thereof, which have good conductivity and low impedance. Of course, it is also possible to substitute the above-mentioned metal powder and conducting carbon fibers with functionally equivalent conducting silver powder, copper paste, conducting silver, or copper gum, which is directly applied over the top of the isolating island 12 to form the conducting island 14.

To avoid the effect of point discharge due to a thin isolating island 12 and accordingly a short isolation distance between the conducting island 14 and the metal substrate 10, the conducting island 14 has an area smaller than that of the corresponding isolating island 12 on which the conducting island 14 is formed, so that a distance d exists between the periphery of the conducting island 14 and the periphery of the isolating island 12.

In the present invention, the isolating islands 12 are formed on the surface of the metal substrate 10 by directly applying the heat-resisting resin material on the metal substrate 10 only at predetermined positions and/or along predetermined paths for forming required conducting circuits. Meanwhile, the isolating islands 12 have shapes and areas determined in accordance with the required conducting circuits. Similarly, the conducting islands 14 are formed by screen printing or applying the conducting materials only on the top of the isolating islands 12. As a result, the conventional etching process for removing unnecessary portions of the isolating and the conducting material from the top of the metal substrate is omitted to largely simplify the whole manufacturing process of the light-emitting diode module 1 and save a large amount of electrical energy, insulating material, and conducting material. Moreover, the problem of environmental pollution caused by the strong acids and bases used in the etching process could be avoided. Since the isolating islands 12 and the conducting islands 14 are formed only at predetermined positions on the surface of the metal substrate 10, there are more exposed areas on the metal substrate 10 to facilitate high-efficient radiation of heat.

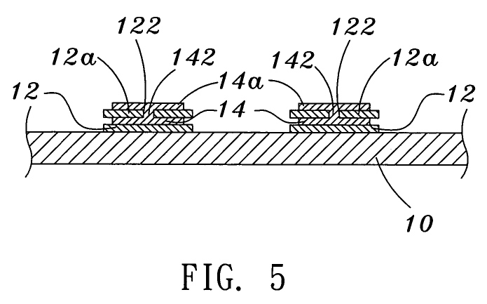

FIG. 5 shows a substrate structure for light-emitting diode module according to a second embodiment of the present invention. In the second embodiment, a plurality of upper isolating islands 12a are further formed on a top of the conducting islands 14, and a plurality of upper conducting islands 14a are further formed on a top of the upper isolating islands 12a. The upper isolating islands 12a located between the conducting islands 14 and the upper conducting islands 14a are provided with a plurality of through holes 122, in each of which a conducting body 142 is provided to electrically connect the conducting islands 14 to the upper conducting islands 14a. In similar manner, more layers of isolating islands and conducting islands could be alternately superposed to build multiple layers of circuits on the surface of the metal substrate 10 to increase the function thereof.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A substrate structure for light-emitting diode module, comprising:
a metal substrate made of a metal sheet having a high heat radiating capacity;
a plurality of isolating islands providing an electrically insulating effect being directly formed on a top surface of said metal substrate at predetermined positions or paths at where required conducting circuits are to be provided; and
a plurality of conducting islands being separately formed on a top of said isolating islands to constitute said required conducting circuits on said metal substrate.

2. The substrate structure for light-emitting diode module as claimed in claim 1, wherein said metal sheet for forming said metal substrate is selected from the group consisting of copper sheets and aluminum alloy sheets.

3. The substrate structure for light-emitting diode module as claimed in claim 1, wherein said isolating islands are formed by directly applying a heat-resisting resin material over said predetermined positions and/or paths on the surface of said metal substrate.

4. The substrate structure for light-emitting diode module as claimed in claim 3, wherein said heat-resisting resin material is selected from the group consisting of polyimide and a composite of BT resin and epoxy resin.

5. The substrate structure for light-emitting diode module as claimed in claim 1, wherein said isolating islands are formed by directly applying a heat conducting resin material over said predetermined positions and/or paths on the surface of said metal substrate.

6. The substrate structure for light-emitting diode module as claimed in claim 1, wherein said isolating islands are formed from a material containing 50%˜90% of resin and 50%˜10% of graphite.

7. The substrate structure for light-emitting diode module as claimed in claim 1, wherein said isolating islands are formed from a material containing 50%˜90% of resin and 50%˜10% of boron nitride.

8. The substrate structure for light-emitting diode module as claimed in claim 1, wherein said conducting islands are formed either by screen printing or directly applying an electrically conducting material on the top of said isolating islands.

9. The substrate structure for light-emitting diode module as claimed in claim 1, wherein said conducting islands are formed from a composite of different types of metal powder or conducting carbon fibers that have good electrical conductivity and low impedance.

10. The substrate structure for light-emitting diode module as claimed in claim 1, wherein said conducting islands are formed from particles of anyone of gold, silver, copper, iron, tin, magnesium, and aluminum, and any of the oxides thereof.

11. The substrate structure for light-emitting diode module as claimed in claim 1, wherein said conducting islands are formed by directly applying conducting silver powder, copper paste, conducting silver, or copper gum on the top of said isolating islands.

12. The substrate structure for light-emitting diode module as claimed in claim 1, wherein each of said conducting islands has an area smaller than that of a corresponding isolating island on which said conducting island is formed, such that a predetermined distance exists between a periphery of said conducting island and a periphery of said corresponding isolating island.

13. The substrate structure for light-emitting diode module as claimed in claim 1, further comprising a plurality of upper isolating islands formed on a top of said conducting islands, and a plurality of upper conducting islands formed on a top of said upper isolating islands, such that said upper conducting islands, said upper isolating islands, said conducting islands, and said isolating islands sequentially superposed on the top surface of said metal substrate from top to bottom to build multiple layers of circuits on said metal substrate.
